(19) United States
(12) Patent Application Publication
(10) Pub. No.: US 2024/0407096 A1
(43) Pub. Date: Dec. 5, 2024

(54) ELECTRONIC SUB-ASSEMBLY INCLUDING CERAMIC SUBSTRATE WITH CONDUCTIVE STRUCTURES PASSING THERETHROUGH

(71) Applicant: Mellanox Technologies, Ltd., Yokneam (IL)

(72) Inventors: Ihab KHOURY, Tel-Aviv (IL); Tzuf LEVY, Nesher (IL); Ilya MARGOLIN, Nesher (IL); Sharon RECHNITZ, Haifa (IL); Dmitry FLITER, Kiryat Yam (IL); David FISCHER, Pardes Hanna-Karkur (IL); Dor DADON, Kibutz Afik (IL)

(73) Assignee: Mellanox Technologies, Ltd., Yokneam (IL)

(21) Appl. No.: 18/203,679

(22) Filed: May 31, 2023

(51) Int. Cl. H05K 1/11; B23K 1/00; H05K 1/14; H05K 3/36

(52) U.S. Cl. CPC H05K 1/119; B23K 1/0016; H05K 1/141; H05K 3/368; B23K 2101/42; H05K 1/0306; H05K 1/18; H05K 3/34; H05K 2201/09045; H05K 2201/10121; H05K 2201/10234

(57) ABSTRACT

An electronic sub-assembly, which may include: a ceramic substrate having a top surface and a bottom surface, a plurality of layers of ceramic material disposed between the top surface and the bottom surface of the substrate, and a plurality of conductive structures passing through the substrate between the top surface and the bottom surface of the substrate; and a ball grid array disposed on the bottom surface of the substrate, the ball grid array comprising a plurality of solder balls, wherein at least a portion of the solder balls are connected to at least a portion of the conductive structures.

### FIELD OF THE INVENTION

The present invention relates to the field of electronic sub-assemblies, and more particularly, to electronic sub-assemblies including ceramic substrates.

### BACKGROUND OF THE INVENTION

Some electronic components (e.g., optical electronic components such as lasers, photodiodes and/or any other suitable components), optical components (e.g., optical lens, ferrules, fibers and/or any other pure optical components), components connectable using Eutectic Gold Tin (AuSn) material and/or other suitable components are typically not disposed directly on printed circuit boards (PCBs). Such components are typically coupled to PCBs using intermediate substrates e.g., made of ceramic. Due to relatively high dielectric constant of the ceramic material (e.g., dielectric constant of about 10), such electronic components are typically electrically connected to PCBs using wire bonds extending externally to ceramic substrates between metallic pads disposed on ceramic substrates and PCBs. However, when transmitting signals of high frequency (e.g., 50 GHz or more), the wire bonds may exhibit significant inductance and/or radiation, which may cause significant crosstalk and/or reflection and/or attenuation of signals passing through the wire bonds.

### SUMMARY OF THE INVENTION

Embodiments of the present invention may provide an electronic sub-assembly which may include: a ceramic substrate having a top surface and a bottom surface, the substrate including: a plurality of layers of ceramic material disposed between the top surface and the bottom surface of the substrate, and a plurality of conductive structures passing through the substrate between the top surface and the bottom surface of the substrate; and a ball grid array disposed on the bottom surface of the substrate, the ball grid array comprising a plurality of solder balls, wherein at least a portion of the solder balls are connected to at least a portion of the conductive structures. The conductive structures may be formed as openings formed through the layers of ceramic material and filled with conductive material. The electronic sub-assembly may include an electronic component disposed on the top surface of the substrate. The electronic component may be connected to at least a portion of the conductive structures. A first subgroup of conductive structures of the plurality of conductive structures are configured to transmit high frequency signals. The conductive structures of the first subgroup may pass through the layers of the substrate from the top surface towards the bottom surface of the substrate in an outer region of the substrate that is adjacent to a perimeter of the substrate. The conductive structures of the first subgroup may extend on the top surface of the substrate from within an inner region of the substrate towards the outer region of the substrate and pass through the layers of the substrate from the top surface towards the bottom surface of the substrate in the outer region. The outer region of the substrate may extend up to 20% of at least one of the width and the length of the substrate from the perimeter of the substrate. A second subgroup of conductive structures of the plurality of conductive structures may be configured to be connected to ground. The conductive structures of the first subgroup may be at least partly surrounded by the conductive structures of the second subgroup. Regions of the substrate that are disposed between the conductive structures of the first subgroup may include only the ceramic material. Regions of the substrate that are disposed between the conductive structures of the first subgroup and the conductive structures of the second subgroup may include only the ceramic material. The electronic sub-assembly may be a transmitter optical sub-assembly (TOSA). The electronic sub-assembly may be a receiver optical sub-assembly (ROSA).

Embodiments of the present invention may provide an electronic assembly which may include: a Printed Circuit Board (PCB) including a plurality of conductive tracks; a sub-assembly including: a supporting structure formed of ceramic material, the supporting structure including: a top surface, a bottom surface, a plurality of layers of ceramic material disposed between the top surface and the bottom surface of the supporting structure, a plurality of conductive structures passing through the supporting structure between the top surface and the bottom surface, and a plurality of pads projecting from the bottom surface of the supporting structure, wherein at least a portion of the pads is connected to at least a portion of the conductive structures and at least a portion of the pads is disposed on the conductive tracks of the PCB; and an electronic component disposed on the top surface of the supporting structure, the electronic component being connected to at least a portion of the conductive structures. The electronic component may be electrically connected to the conductive tracks of the PCB via the conductive structures passing through the supporting structures and the pads. The pads may include solder balls arranged in a ball grid array

(BGA) on the bottom surface of the supporting structure. A first subgroup of conductive structures of the plurality of conductive structures may be configured to transmit high frequency signals. The conductive structures of the first subgroup may pass through the layers of the supporting structure from the top surface towards the bottom surface of the supporting structure in an outer region of the supporting structure that is adjacent to a perimeter of the supporting structure. The outer region of the supporting structure may extend up to 20% of at least one of the width and the length of the supporting structure from the perimeter of the supporting structure. A second subgroup of conductive structures of the plurality of conductive structures may be configured to be connected to ground. The conductive structures of the first subgroup may be at least partly surrounded by the conductive structures of the second subgroup. Regions of the supporting structure that are disposed between the conductive structures of the first subgroup may include only the ceramic material. Regions of the supporting structure that are disposed between the conductive structures of the first subgroup and the conductive structures of the second subgroup may include only the ceramic material.

Embodiments of the present invention may provide a method of assembling an electronic assembly, which may include: providing a sub-assembly including: a substrate formed of ceramic material and having a top surface and a bottom surface; and a plurality of solder balls projecting from the bottom surface of the substrate; placing and soldering an electronic component to the top surface of the substrate; upon soldering of the electronic to the substrate, placing and soldering the substrate to a Printed Circuit Board (PCB) by the solder balls; and upon soldering of the substrate to the PCB, placing soldering an optical component to the top surface of the substrate.

### BRIEF DESCRIPTION OF THE DRAWINGS

For a better understanding of embodiments of the invention and to show how the same can be carried into effect, reference is made, purely by way of example, to the accompanying drawings in which like numerals designate corresponding elements or sections throughout. In the accompanying drawings:

FIGS. 1A, 1B, IC and ID are schematic illustrations of an electronic sub-assembly including a transmitter optical sub-assembly (TOSA), according to some embodiments of the invention;

FIGS. 2A, 2B, 2C and 2D are schematic illustrations of the electronic sub-assembly including a receiver optical sub-assembly (ROSA), according to some embodiments of the invention;

FIGS. 3A, 3B, and 3C are schematic illustrations of an electronic assembly including the electronic sub-assemblies FIGS. 1A-ID and FIGS. 2A-2D, according to some embodiments of the invention;

FIGS. 4A, 4B and 4C are schematic illustrations of a substrate for the electronic sub-assembly, according to some embodiments of the invention;

FIGS. 5A, 5B, 5C, 5D and FIGS. 5E, 5F are schematic illustrations of the electronic sub-assembly indicating different subgroups of conductive structures and different subgroups of pads of a substrate of the electronic sub-assembly, according to some embodiments of the invention; and

FIG. 6 is a flowchart of a method for assembling an electronic assembly, according to some embodiments of the invention.

It will be appreciated that, for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following description, various aspects of the present invention are described. For purposes of explanation, specific configurations and details are set forth in order to provide a thorough understanding of the present invention. However, it will also be apparent to one skilled in the art that the present invention can be practiced without the specific details presented herein. Furthermore, well known features can have been omitted or simplified in order not to obscure the present invention. With specific reference to the drawings, it is stressed that the particulars shown are by way of example and for purposes of illustrative discussion of the present invention only and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention can be embodied in practice.

Before at least one embodiment of the invention is explained in detail, it is to be understood that the invention is not limited in its application to the details of construction and the arrangement of the components set forth in the following description or illustrated in the drawings. The invention is applicable to other embodiments that can be practiced or carried out in various ways as well as to combinations of the disclosed embodiments. Also, it is to be understood that the phraseology and terminology employed herein is for the purpose of description and should not be regarded as limiting.

Embodiments of the present invention may improve connection (e.g., electrical connection) of electronic components to a printed circuit board (PCB), especially connection of electronic components operating or transmitting signals having high frequencies, for example, frequencies of 50 GHz or more.

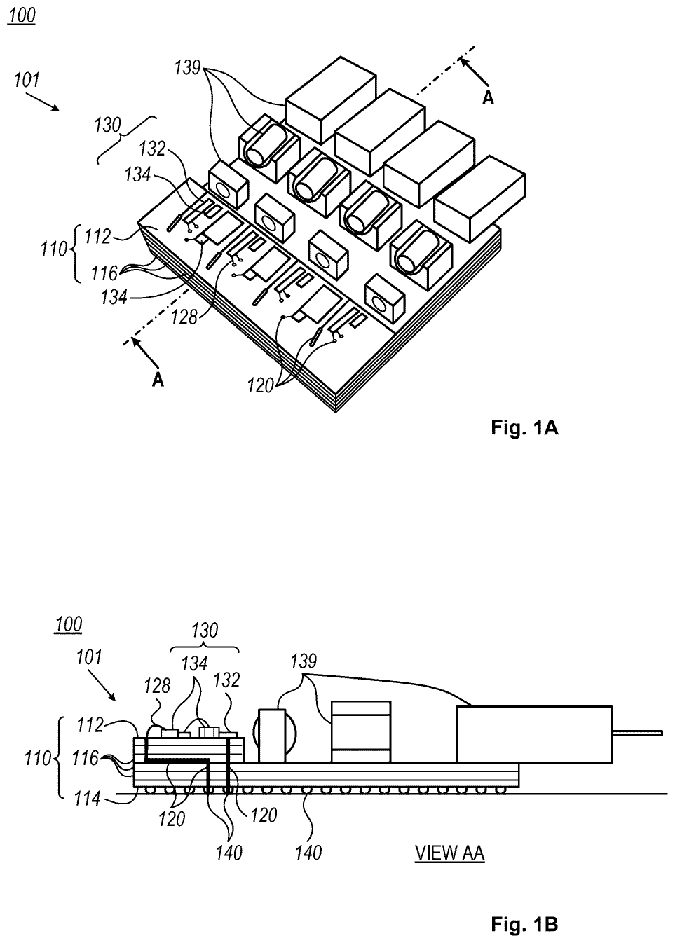

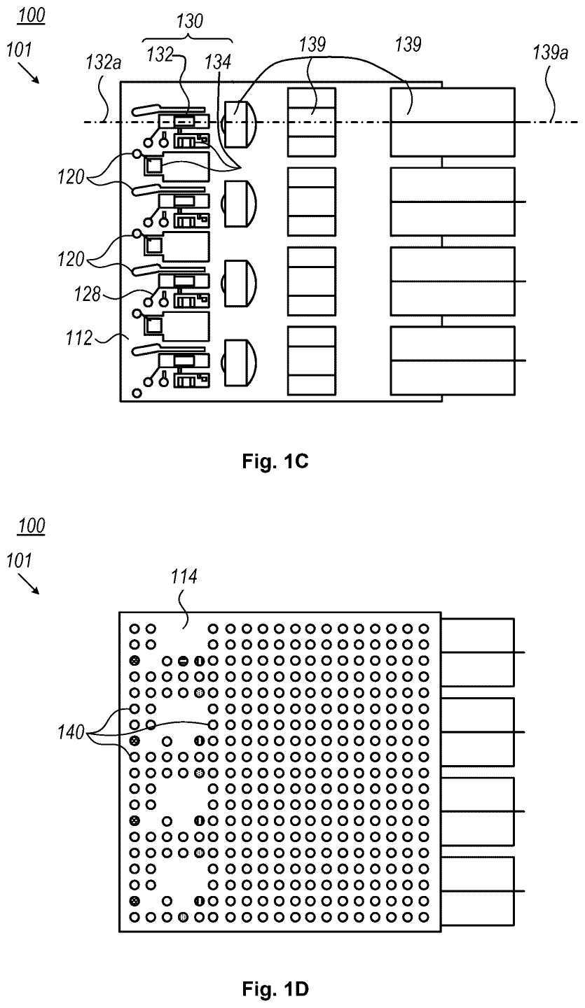

Reference is made to FIGS. 1A, 1B, IC and ID, which are schematic illustrations of an electronic sub-assembly 100 including a transmitter optical sub-assembly (TOSA) 101, according to some embodiments of the invention.

FIG. 1A shows a perspective view of TOSA 101; FIG. 1B shows a partial section view of TOSA 101 along line AA of FIG. 1A; and FIGS. 1C and 1D show top and bottom views, respectively, of TOSA 101.

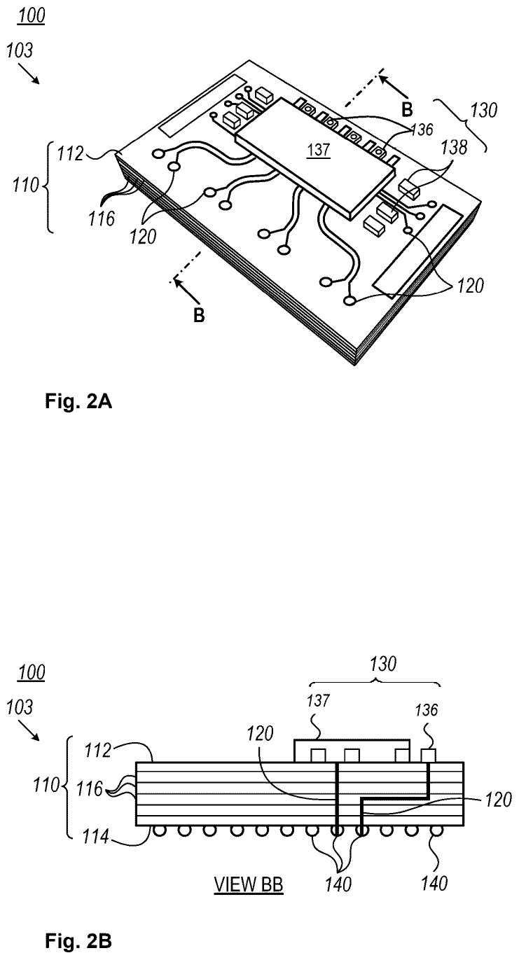

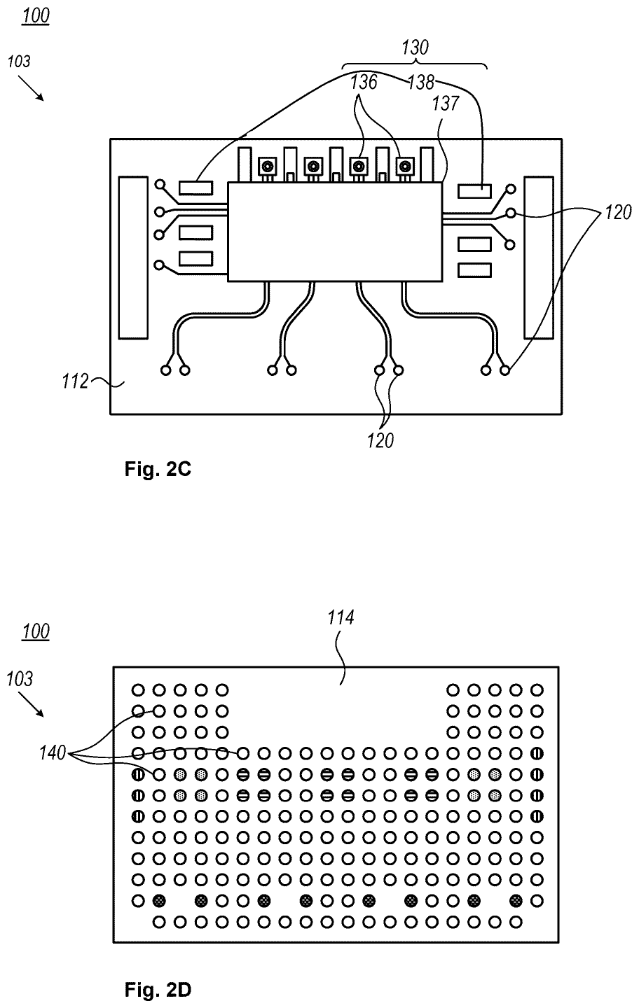

Reference is also made to FIGS. 2A, 2B, 2C and 2D, which are schematic illustrations of electronic sub-assembly 100 including a receiver optical sub-assembly (ROSA) 103, according to some embodiments of the invention.

FIG. 2A shows a perspective view of ROSA 103; FIG. 2B shows a partial section view of ROSA 103 along line BB of FIG. 2A; and FIGS. 2C and 2D show top and bottom views, respectively, of ROSA 103.

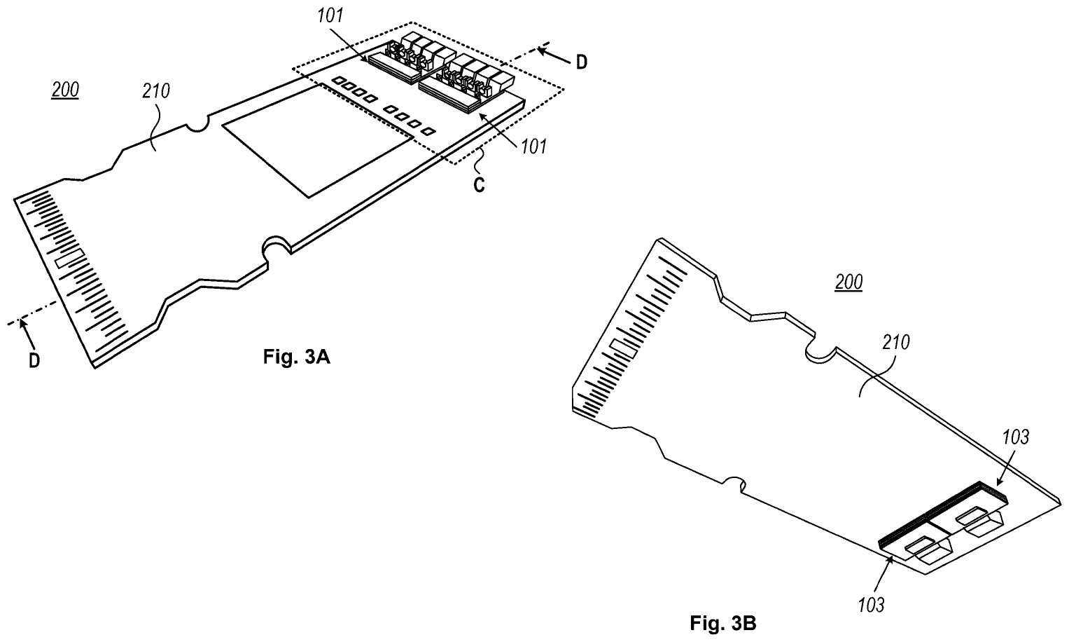

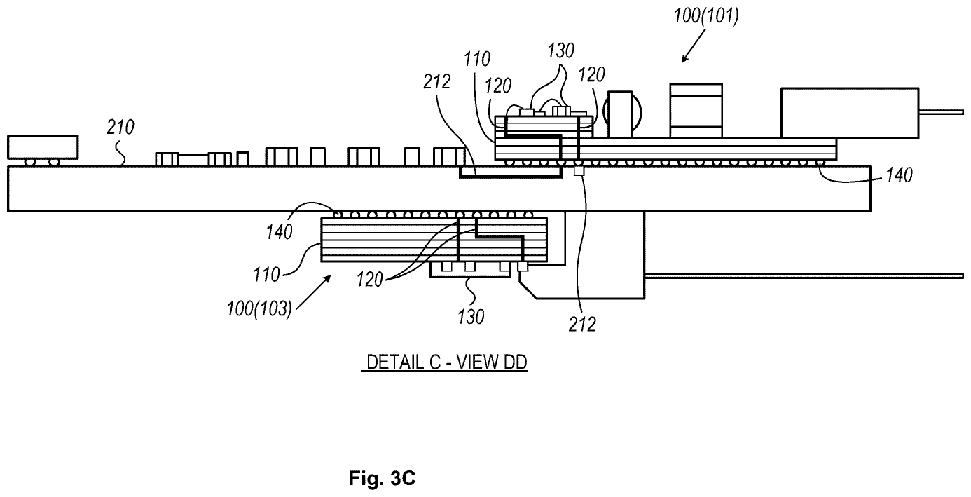

Reference is also made to FIGS. 3A, 3B and 3C, which are schematic illustrations of an electronic assembly 200 including electronic sub-assemblies 100 of FIGS. 1A-ID and FIGS. 2A-2D, according to some embodiments of the invention.

FIGS. 3A and 3B show different perspective views of electronic assembly 200; and FIG. 3C shows partial section view of enlarged portion C of electronic assembly 200 along line DD of FIG. 3A.

While TOSA 101 and ROSA 103 of a network interface device (e.g., small form-factor pluggable (SFP) device) are shown as examples of electronic sub-assembly 100, electronic sub-assembly 100 may include sub-assemblies other than TOSA 101 and ROSA 103 and/or may operate in devices other than SFP device.

Electronic sub-assembly 100 may include a substrate (e.g., supporting structure) 110. Substrate 110 may be formed of ceramic material (e.g., such as Aluminum nitride (AIN) or any other suitable ceramic material). Substrate 110 is also referred hereinbelow as “ceramic substrate 110”. Substrate 110 may have a top surface 112 and a bottom surface 114. Bottom surface 114 may be opposed to top surface 112. Bottom surface 114 of substrate 110 may face a PCB when substrate 110 is disposed on the PCB. Substrate 110 may include a plurality of layers 116 of ceramic material disposed between top surface 112 and bottom surface 114 of substrate 110.

Substrate 110 may include a plurality of conductive (e.g., electrically conductive) structures (e.g., vias or interconnects) 120. Conductive structures 120 may extend (e.g., pass) through substrate 110 (e.g., as shown in FIGS. 1B and 2B). Conductive structures 120 may extend between top surface 112 and bottom surface 114 of substrate 110. Conductive structures 120 may extend through layers 116 of ceramic material of substrate 110. Conductive structures 120 may be formed as holes or openings formed (e.g., drilled) through layers 116 of substrate 110 and filled with electrically conductive material, for example tungsten, another metal, or any other suitable material. Conductive structures 120 may form interconnects (e.g., electrical interconnects) between top surface 112 and bottom surface 114 of substrate 110.

Electronic sub-assembly 100 may include electronic components 130. Electronic components 130 may be disposed on top surface 112 of substrate 110. Electronic components 130 may be connected (e.g., mechanically and/or electrically connected) to conductive structures 120 passing through substrate 110. Each of electronic components 130 may be connected (e.g., electrically connected) to at least a portion of conductive structures 120. In some embodiments, at least a portion, set or subset of electronic components 130 may be soldered to at least a portion conductive structures 120 to connect (e.g., mechanically and electrically connect) the respective electronic components 130 to the respective conductive structures 120. In some embodiments, at least a portion of electronic components 130 may be connected (e.g., electrically connected) to at least a portion of conductive structures 120 using wire bonds 128. In some embodiments, no wire bonds 128 are used to connect electronic components 130 to conductive structures 120.

For example, TOSA 101 may include electronic components 130 such as lasers 132 (e.g., electro-absorption modulated lasers (EMLs) or any other suitable lasers) and other electronic components 134 (e.g., capacitors or any other suitable components) that need to be disposed in a vicinity of lasers 132 (e.g., as shown in FIGS. 1A-1C). In another example, ROSA 103 may include electronic components 130 such as photodiodes 136 or any other electronic components that need to be disposed in a vicinity of photodiodes 136 such as a chip 137 and other suitable components 138 (e.g., as shown in FIGS. 2A-2C).

Electronic sub-assembly 100 may include additional components disposed on top surface 112 of substrate 110. For example, TOSA 101 may include ferrule receptacles and optical lens assemblies 139 disposed on (e.g., soldered to) top surface 112 of substrate 110. Each of assemblies 139 may have a longitudinal axis 139a that is aligned with a longitudinal axis 132a of one of lasers 132 (e.g., as shown in FIG. 1C). Electronic sub-assembly 100 may include any other suitable components disposed on top surface 112 of substrate 110.

Electronic sub-assembly 100 may include a plurality of pads 140. Pads 140 may be disposed on bottom surface 114 of substrate 110. Pads 140 may project from bottom surface 114 of substrate 110. Pads 140 may be arranged in for example a grid array on bottom surface 114 of substrate 110. Pads 140 may include hemispheres or balls (e.g., solder balls) arranged in a ball grid array (BGA) on bottom surface 114 of substrate 110 (e.g., as shown in Figs. ID and 2D). Pads 140 may be formed of conductive material. For example, pads 140 may be formed from SAC305 material (which is a lead-free alloy that contains 96.5% tin, 3% silver, and 0.5% copper) or any other suitable conductive material, e.g., suitable for soldering. At least a portion of pads 140 may be connected (e.g., electrically connected) to conductive structures 120 passing through substrate 110. Each of pads 140 may be connected (e.g., electrically connected) to one of conductive structures 120. At least one of pads 140 may be connected (e.g., electrically connected) to two or more of conductive structures 120. At least one of conductive structures 120 may be electrically connected to two or more of pads 140. Other structures, shapes, materials and arrangements may be used for conductors, conductive structures, conductive tracks, pads, etc. discussed herein.

Electronic sub-assembly 100 may be disposed on a PCB 210 of electronic assembly 200 (e.g., as shown in FIGS. 3A-3C). For example, FIGS. 3A-3C show electronic sub-assemblies 100 including TOSA 101 and ROSA 103 placed on opposing sides of PCB 210. PCB 210 may be formed from for example EM-890 material or any other suitable material. Pads 140 of electronic sub-assembly 100 may be disposed on conductive tracks 212 of PCB 220 (e.g., as shown in FIG. 3D). Conductive tracks 212 of PCB 210 may be formed from for example copper that may be covered with a finish material such as Electroless Nickel Electroless Palladium Immersion Gold (ENEPIG) or any other suitable finish material. Pads 140 may be connected (e.g., electrically) to conductive tracks 212 of PCB 210. Pads 140 may be soldered to conductive tracks 212 of PCB 210 to connect (e.g., mechanically and electrically connect) pads 140 to conductive tracks 212 of PCB 210

Electronic components 130 of electronic sub-assembly 100 may be electrically connected to conductive tracks 212 of PCB 210 using conductive structures 120 passing through substrate 110 and pads 140 disposed on bottom surface 114 of substrate 110 of electronic sub-assembly 100 (e.g., as shown in FIG. 3D). Parameters of conductive structures 120 and of pads 140 may be predefined to, for example, compensate for relatively high dielectric constant of the ceramic material (e.g., dielectric constant of about 10) from which substrate 110 is formed to provide a desired impedance matching (e.g., by minimizing signal reflections and/or maximizing signal power transfer) and/or to ensure a desired integrity of signals transmitted therethrough. Conductive structures 120 may be formed through layers 116 of ceramic substrate 110 with high precision and known tolerances to ensure the desired impedance matching and/or the desired signal integrity in the actual product.

The parameters taken into account to provide the desired impedance matching and/or to ensure the desired integrity of signals may, for example, include geometry of each of conductive structures 120. The parameters may include dimensions of each of conductive structures 120. The parameters may include the position of each of conductive structures 120 in substrate 110. The parameters may include the path(s) along which each of conductive structures 120 passes through substrate 110. The parameters may include distance between conductive structures 120. The parameters may include position of pads 140 on bottom surface 114 of substrate 110. The parameters may include relative position between (i) conductive structures 120 that transmit high frequency signals and (ii) ground planes provided by conductive structures 120 that are electrically connected (or configured to be connected) to ground (e.g., electrical ground) using respective pads

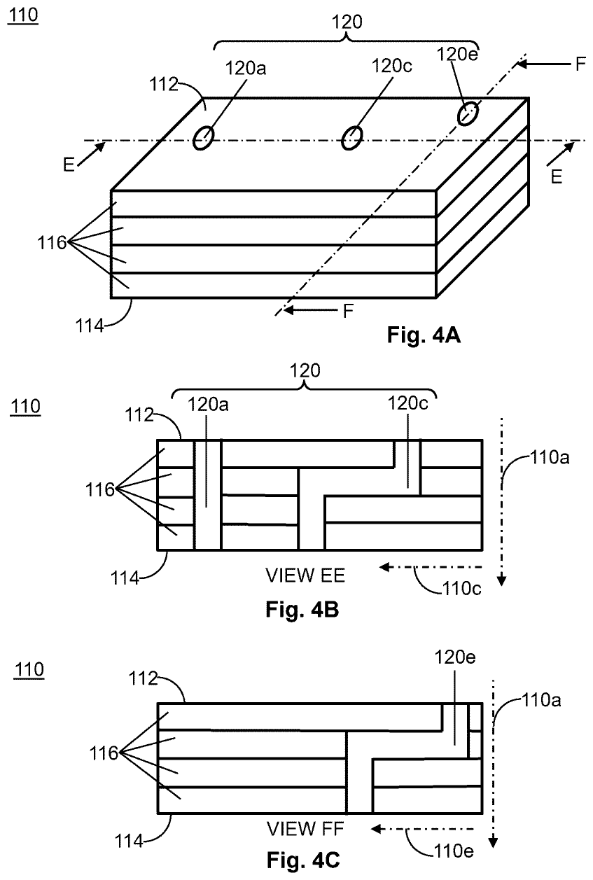

Reference is made to FIGS. 4A, 4B and 4C, which are schematic illustrations of a substrate 110a for electronic sub-assembly 100, according to some embodiments of the invention.

FIG. 4A shows a perspective view of substrate 110a; FIG. 4B shows a sectional view of substrate 110a along line EE of FIG. 4A; and FIG. 4C shows a sectional view of substrate 110a along line FF of FIG. 4A.

Substrate 110a (e.g., such as substrate 110 described herein) formed of layers 116 may provide flexibility in designing and forming geometries and paths of conductive structures 120 through substrate 110, for example based on the parameters described hereinabove. For example, substrate 110a formed from layers 116 may allow designing and forming straight conductive structures such as conductive structures 120a extending through layers 116 of substrate 110a in a direction 100a that is parallel to top surface 112 and bottom surface 114 (e.g., as shown in FIG. 4B). Substrate 110a formed from layers 116 may allow designing and forming curved conductive structures such as a conductive structure 120c portions of which extend in direction 100a and a portion of which extends in a direction 100c that is transverse to direction 100a (e.g., as shown in FIG. 4B) and/or such as a conductive structure 120e portions of which extend in direction 100a and a portion of which extends in a direction 100e that is transverse to directions 100a, 100c (e.g., as shown in FIG. 4B). At least a portion of conductive structures 120 may fuse or merge into a single conductive structure in one of layers 116 of substrate 110a.

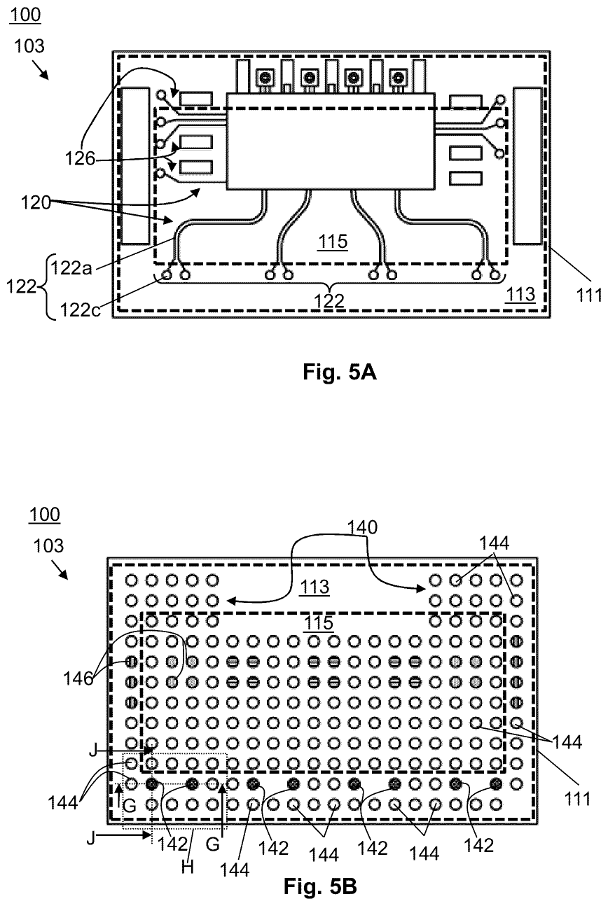

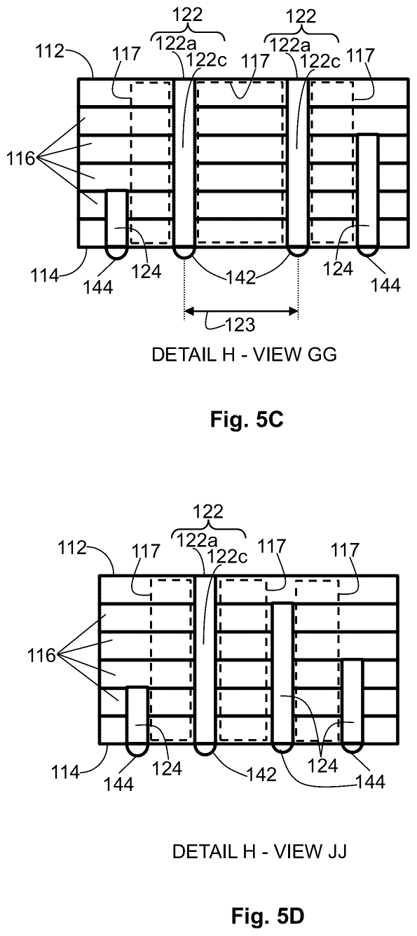

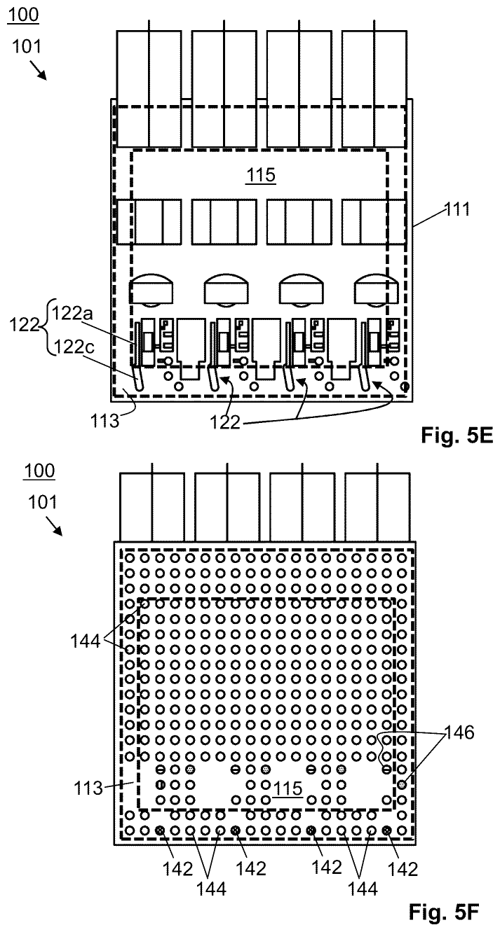

Such flexibility in designing and forming geometries and paths of conductive structures 120 through substrate 110 may be important for achieving the desired impedance matching and/or the desired integrity of signals transmitted therethrough, especially of signal having high frequency of for example 50 GHz and more (e.g., as described below with respect to FIGS. 5A, 5B and 5C).

Reference is made to FIGS. 5A, 5B, 5C, 5D and FIGS. 5E, 5F, which are schematic illustrations of electronic sub-assembly 100 indicating different subgroups conductive structures 120 and different subgroups of pads 140 of substrate 110 of electronic sub-assembly 100, according to some embodiments of the invention.

FIG. 5A and 5B show top and bottom views, respectively, of electronic sub-assembly 100 including ROSA 103; and FIG. 5C shows a section view of enlarged portion H of electronic assembly 100 including ROSA 103 along line GG of FIG. 5B; and FIG. 5D shows a section view of enlarged portion H of electronic sub-assembly 100 including ROSA 103 along line JJ of FIG. 5B. FIG. 5E and 5F show top and bottom views, respectively, of electronic sub-assembly 100 including TOSA 101.

Substrate 110 may include a first subgroup of conductive structures 122 that may transmit high frequency signals (e.g., 50 GHz and more) (e.g., as shown in FIGS. 5A, 5C, 5D, 5E). Substrate 110 may include a first subgroup of pads 142 connected to conductive structures 122 (e.g., as shown in FIGS. 5B, 5C, 5D, 5F). Substrate 110 may include a second subgroup of pads 144 connected (or configured to be connected) to ground (e.g., as shown in FIG. 5B, 5C, 5D, 5E). Substrate 110 may include a second subgroup of conductive structures 124 that are connected to ground by pads 144 (e.g., as shown in FIGS. 5C and 5D). Substrate 1 10 may include a third subgroup of conductive structures 126 that may transmit signals other than high frequency signals (e.g., signals having frequency less than 50 GHz) (e.g., as shown in FIG. 5A). Substrate 110 may include a third subgroup of pads 146 connected to conductive structures 126 (e.g., as shown in FIG. 5B).

Conductive structures 122 transmitting high frequency signals may pass through layers 116 of substrate 110 (e.g., from top surface 112 towards bottom surface of substrate 114) in an outer region 113 of substrate 110 that is adjacent to an outer edge or perimeter 111 of substrate 110. Pads 142 connected to conductive structures 122 may be also disposed on bottom surface 114 of substrate 110 in outer region 113. Conductive structures 146 that transmit signals other than high frequency signals and/or pads 146 connected thereto and/or conductive structures 124 connected to ground and/or pads 144 connected thereto may be disposed in outer region 113 and/or in inner region 115 of substrate 110 (e.g., as shown in FIGS. 5A, 5B, 5E, 5F).

For example, each of at least a part of conductive structures 122 transmitting high frequency signals may include: (i) a first portion 122a extending on top surface 112 (or in upper layers 116 adjacent to top surface 112) from within an inner region 115 (e.g., surrounded by outer region 113) to outer region 113 of substrate 110, and (ii) a second portion 122c extending through layers 116 from top surface 112 towards bottom surface 114 of substrate 110 within outer region 113 and ending at respective conductive pad 142. First portion 122a of respective conductive structure 122 may be straight or curved (e.g., as shown in FIG. 5A). Second portion 122c of respective conductive structure 122 may be straight (e.g., as shown in FIG. 5C), curved (e.g., as described above with respect to FIG. 4C) or include both straight and curved sub-portions.

Outer region 113 in which conductive structures 122 that transmit high frequency signals pass through layers 116 of substrate 110 may extend up to 20% of the length and/or the width of substrate 110 from edge 111 of substrate 110. In the example of TOSA 101 having the length/width of 7 mm, outer region 113 may extend up to 0.35 mm from edge 111 of substrate 110 (e.g., which is about 5% of the length/width of substrate 110). In the example of ROSA 103 having the length/width of 4.55 mm, outer region 113 may extend up to 0.70 mm from edge 111 of substrate 110 (e.g., which is about 15% of the length/width of substrate 110).

Positioning conductive structures 122 that transmit high frequency signals and/or pads 142 connected thereto in outer region 113 of substrate 110 may ensure that high frequency signals transmitted therethrough have the desired integrity.

Substrate 110 may include regions 117 disposed (i) between conductive structures 122 transmitting high frequency signals and conductive structures 124 connected to ground and/or (ii) between adjacent conductive structures 122 (e.g., as shown in FIGS. 5C and 5D). Regions 117 do not include metal material (e.g., conductive structures 120 or any other suitable metal structures). For example, regions 117 may include only ceramic material from which substrate 110 is formed. Having regions 117 with no metal material (i) between conductive structures 122 transmitting high frequency signals and conductive structures 124 connected to ground and/or (ii) between adjacent conductive structures 122 may ensure that high frequency signals transmitted through conductive structures 122 have the desired integrity. The shape and/or the size and/or the contour of each of regions 117 may be predetermined based on the desired integrity of the high speed signals transmitted through conductive structures 122 and/or based on the type of the electronic sub-assembly (e.g., TOSA 101, ROSA 103 and/or any other suitable electronic sub-assembly). Distance 123 between adjacent conductive structures 122 (e.g., as schematically indicated in FIG. 5C) may be predetermined to ensure that high frequency signals transmitted through conductive structures 122 have the desired integrity.

Part of conductive structures 124 and/or pads 144 connected to ground may be disposed around conductive structures 122 and/or pads 142 transmitting high frequency signals. Positioning part of conductive structures 124 and/or pads 144 connected to ground around conductive structures 122 and/or pads 142 transmitting high frequency signals may, for example, ensure that high frequency signals transmitted therethrough have the desired integrity. The positioning of conductive structures 124 and/or pads 144 with respect to conductive structures 122 and/or pads 142 may be based on the type of the electronic sub-assembly. For example, in a differential pair electronic sub-assembly such as ROSA 103, conductive structures 122 and/or pads 142 may be disposed in the second row of conductive structures 122 and pads 122 relative to edge 111 of substrate 110 such that conductive structures 122 and/or pads 142 are entirely surrounded by conductive structures 124 and/or pads 144 connected to ground (e.g., as shown in FIG. 5B). In another example, in a single ended electronic sub-assembly such as TOSA 101, conductive structures 122 and/or pads 142 may be disposed in the first row of conductive structures 122 and pads 122 relative to edge 111 of substrate 110 such that conductive structures 122 and/or pads 142 are partly surrounded by conductive structures 124 and/or pads 144 connected to ground (e.g., as shown in FIG. 5F).

In prior art systems, electronic components such as lasers and other related electronic components disposed on the ceramic substrate are typically electrically connected to the PCB using wire bonds extending from metallic pads disposed on the ceramic substrate to the PCB externally to ceramic substrate. When transmitting signals of high frequency (e.g., 50 GHz or more), the wire bonds may exhibit significant inductance and/or radiation, which may cause significant crosstalk and/or reflection and/or attenuation of signals passing through the wire bonds. Unlike in prior art, electronic components 130 of disclosed electronic sub-assembly 100 are connected (e.g., electrically connected) to conductive tracks 212 of the PCB 210 using conductive structures 120 passing through ceramic substrate 110 and pads 140 disposed on bottom surface 114 of ceramic substrate 110 of electronic sub-assembly 100. Connecting electronic components 130 to conductive tracks 212 of PCB 210 using conductive structures 120 passing through ceramic substrate 110 may ensure a desired integrity of signals (especially of signals having high frequencies, for example frequencies of 50 GHz or more) transmitted therethrough and significantly reduce crosstalk and/or reflection and/or attenuation of transmitted signals as compared to signals transmitted via prior art wire bonds.

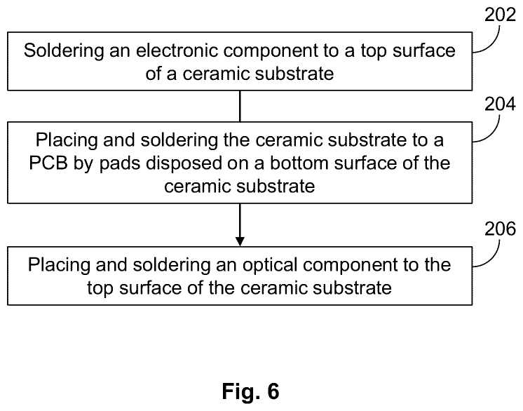

Reference is made to FIG. 6, which is a flowchart of assembling an electronic assembly, according to some embodiments of the invention.

The operations may be performed in a reflow oven device or any other suitable system.

In operation 202, an electronic component (e.g., a non-optical electronic component such as electronic components 134, 137, 138 described hereinabove, an optical electronic component such as laser 132, photodiode 136 and/or any other suitable electronic component) may be soldered to a top surface of a ceramic substrate (e.g., such as substrate 110 described hereinabove).

In operation 204, upon soldering of the electronic component to the substrate, the ceramic substrate may be placed and soldered to a PCB by pads (e.g., such as pads 140 for example solder balls) disposed on a bottom surface of the ceramic substrate.

In operation 206, upon soldering of the ceramic substrate to the PCB, an optical component (e.g., such as ferrules and optical lens assembly 139 and/or any other suitable pure optical component) may be placed and soldered to the top surface of the ceramic substrate.

It may be important to place and solder the optical component to the ceramic substrate after the soldering of ceramic substrate to the PCB because soldering of the ceramic substrate to the PCB may require temperatures that are greater than the optical component may sustain.

In the above description, an embodiment is an example or implementation of the invention. The various appearances of “one embodiment”, “an embodiment”, “certain embodiments” or “some embodiments” do not necessarily all refer to the same embodiments. Although various features of the invention can be described in the context of a single embodiment, the features can also be provided separately or in any suitable combination. Conversely, although the invention can be described herein in the context of separate embodiments for clarity, the invention can also be implemented in a single embodiment. Certain embodiments of the invention can include features from different embodiments disclosed above, and certain embodiments can incorporate elements from other embodiments disclosed above. The disclosure of elements of the invention in the context of a specific embodiment is not to be taken as limiting their use in the specific embodiment alone. Furthermore, it is to be understood that the invention can be carried out or practiced in various ways and that the invention can be implemented in certain embodiments other than the ones outlined in the description above.

Although embodiments of the invention are not limited in this regard, the terms “plurality” and “a plurality” as used herein can include, for example, “multiple” or “two or more”. The terms “plurality” or “a plurality” can be used throughout the specification to describe two or more components, devices, elements, units, parameters, or the like. The term set when used herein can include one or more items.

The invention is not limited to those diagrams or to the corresponding descriptions. Meanings of technical and scientific terms used herein are to be commonly understood as by one of ordinary skill in the art to which the invention belongs, unless otherwise defined. While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

1. An electronic sub-assembly comprising:
a ceramic substrate having a top surface and a bottom surface, the substrate comprising:
a plurality of layers of ceramic material disposed between the top surface and the bottom surface of the substrate, and
a plurality of conductive structures passing through the substrate between the top surface and the bottom surface of the substrate; and
a ball grid array disposed on the bottom surface of the substrate, the ball grid array comprising a plurality of solder balls, wherein at least a portion of the solder balls are connected to at least a portion of the conductive structures.

2. The electronic sub-assembly of claim 1, wherein the conductive structures are formed as openings formed through the layers of ceramic material and filled with conductive material.

3. The electronic sub-assembly of claim 1, comprising an electronic component disposed on the top surface of the substrate, the electronic component being connected to at least a portion of the conductive structures.

4. The electronic sub-assembly of claim 1,
wherein a first subgroup of conductive structures of the plurality of conductive structures are configured to transmit high frequency signals, and
wherein the conductive structures of the first subgroup pass through the layers of the substrate from the top surface towards the bottom surface of the substrate in an outer region of the substrate that is adjacent to a perimeter of the substrate.

5. The electronic sub-assembly of claim 1,
wherein a first subgroup of conductive structures of the plurality of conductive structures are configured to transmit high frequency signals, and
wherein the conductive structures of the first subgroup extend on the top surface of the substrate from within an inner region of the substrate towards an outer region of the substrate and pass through the layers of the substrate from the top surface towards the bottom surface of the substrate in the outer region, the outer region being adjacent to a perimeter of the substrate.

6. The electronic sub-assembly of claim 4, wherein the outer region of the substrate extends up to 20% of at least one of the width and the length of the substrate from the perimeter of the substrate.

7. The electronic sub-assembly of claim 4, wherein a second subgroup of conductive structures of the plurality of conductive structures are configured to be connected to ground, the conductive structures of the first subgroup being at least partly surrounded by the conductive structures of the second subgroup.

8. The electronic sub-assembly of claim 4, wherein regions of the substrate that are disposed between the conductive structures of the first subgroup comprise only the ceramic material.

9. The electronic sub-assembly of claim 7, wherein regions of the substrate that are disposed between the conductive structures of the first subgroup and the conductive structures of the second subgroup comprise only the ceramic material.

10. The electronic sub-assembly of claim 1, wherein the electronic sub-assembly is a transmitter optical sub-assembly (TOSA).

11. The electronic sub-assembly of claim 1, wherein the electronic sub-assembly is a receiver optical sub-assembly (ROSA).

12. An electronic assembly comprising:
a Printed Circuit Board (PCB) comprising a plurality of conductive tracks;
a sub-assembly comprising:
a supporting structure formed of ceramic material, the supporting structure comprising:
a top surface,
a bottom surface,
a plurality of layers of ceramic material disposed between the top surface and the bottom surface of the supporting structure,
a plurality of conductive structures passing through the supporting structure between the top surface and the bottom surface, and
a plurality of pads projecting from the bottom surface of the supporting structure, wherein at least a portion of the pads is connected to at least a portion of the conductive structures and at least a portion of the pads is disposed on the conductive tracks of the PCB; and
an electronic component disposed on the top surface of the supporting structure, the electronic component being connected to at least a portion of the conductive structures.

13. The electronic assembly of claim 12, wherein the electronic component is electrically connected to the conductive tracks of the PCB via the conductive structures passing through the supporting structures and the pads.

14. The electronic assembly of claim 12, wherein the pads comprise solder balls arranged in a ball grid array (BGA) on the bottom surface of the supporting structure.

15. The electronic assembly of claim 12,
wherein a first subgroup of conductive structures of the plurality of conductive structures are configured to transmit high frequency signals, and
wherein the conductive structures of the first subgroup pass through the layers of the supporting structure from the top surface towards the bottom surface of the supporting structure in an outer region of the supporting structure that is adjacent to a perimeter of the supporting structure.

16. The electronic sub-assembly of claim 15, wherein the outer region of the supporting structure extends up to 20% of at least one of the width and the length of the supporting structure from the perimeter of the supporting structure.

17. The electronic sub-assembly of claim 15, wherein a second subgroup of conductive structures of the plurality of conductive structures are configured to be connected to ground, the conductive structures of the first subgroup being at least partly surrounded by the conductive structures of the second subgroup.

18. The electronic sub-assembly of claim 15, wherein regions of the supporting structure that are disposed between the conductive structures of the first subgroup comprise only the ceramic material.

19. The electronic sub-assembly of claim 15, wherein regions of the supporting structure that are disposed between the conductive structures of the first subgroup and the conductive structures of the second subgroup comprise only the ceramic material.

20. A method of assembling an electronic assembly, the method comprising:
providing a sub-assembly comprising:
a substrate formed of ceramic material and having a top surface and a bottom surface; and
a plurality of solder balls projecting from the bottom surface of the substrate;
placing and soldering an electronic component to the top surface of the substrate;
upon soldering of the electronic to the substrate, placing and soldering the substrate to a Printed Circuit Board (PCB) by the solder balls; and
upon soldering of the substrate to the PCB, placing soldering an optical component to the top surface of the substrate.
